(19) United States
(12) Patent Application Publication
(10) Pub. No.: US 2014/0084466 A1
(43) Pub. Date: Mar. 27, 2014

(54) MANGANESE SILICATE FILM FORMING METHOD, PROCESSING SYSTEM, SEMICONDUCTOR DEVICE MANUFACTURING METHOD AND SEMICONDUCTOR DEVICE

(71) Applicant: TOKYO ELECTRON LIMITED, Tokyo (JP)

(72) Inventors: Kenji MATSUMOTO, Nirasaki City (JP); Tatsufumi HAMADA, Nirasaki City (JP)

(73) Assignee: TOKYO ELECTRON LIMITED, Tokyo (JP)

(21) Appl. No.: 14/035,570

(22) Filed: Sep. 24, 2013

(30) Foreign Application Priority Data
Sep. 24, 2012 (JP) 2012-209593

(51) Int. Cl. H01L 21/768

(52) U.S. Cl. CPC H01L 21/76864
USPC 257/741; 118/724; 438/664

(57) ABSTRACT

According to an embodiment of present disclosure a manganese silicate film forming method for forming a manganese silicate film by transforming metal manganese to silicate. The method includes forming a metal manganese film on a silicon-containing base by using a manganese compound gas; annealing the metal manganese film in an oxidizing atmosphere after the formation of the metal manganese film; and forming a manganese silicate film by annealing the metal manganese film in a reducing atmosphere after the annealing of the metal manganese film in the oxidizing atmosphere.

### CROSS-REFERENCE TO RELATED APPLICATION

This application claims the benefit of Japanese Patent Application No. 2012-209593, filed on Sep. 24, 2012, in the Japan Patent Office, the disclosure of which is incorporated herein in its entirety by reference.

### TECHNICAL FIELD

The present disclosure relates to a manganese silicate film forming method, a processing system, a semiconductor device manufacturing method and a semiconductor device.

### BACKGROUND

With a view to form an ultrafine copper wiring line in a semiconductor device, there is the formation of a barrier film composed of a manganese silicate film. In this technology, a metal manganese film is formed by depositing metal manganese on a silicon-containing oxide film formed on a substrate using a manganese precursor. Then, the substrate having the metal manganese film formed thereon is annealed for 5 minutes at a temperature of 300 to 400 degrees C. in the atmosphere added with a small amount of oxygen. Thus, as the metal manganese is turned to silicate by reacting with the silicon of the base silicon-containing oxide film and the oxygen, a manganese silicate film is formed. Also, the annealing is carried out after a copper film is formed on the metal manganese film.

However, even if the metal manganese is deposited on the silicon-containing oxide film, it is not possible to satisfactorily turn the metal manganese to the silicate by merely carrying out the annealing. Thus, a manganese silicate (MnSiO₃ or Mn₂SiO₄) film having a desired thickness may not be formed.

For example, the reaction formula of metal manganese and a base silicon oxide film (SiO₂) is represented as: Mn+SiO₂→MnSiO₂, where MnSiO₂ lacks one oxygen atom as compared with chemically-stable MnSiO₃. In other words, the “oxidizing species” are not sufficient to have the metal manganese react with a base material and to turn the metal manganese to the silicate.

In the meantime, when manganese oxides (MnOx) are formed by oxidizing metal manganese, manganese can have a plurality of valences. For that reason, the manganese oxide can diverge into MnO (bivalent), Mn₃O₄ (bivalent and trivalent), Mn₂O₃ (trivalent) and MnO₂ (tetravalent). There are many indefinite factors when applying manganese to a semiconductor device or to a structure within the semiconductor device. More specifically, when manganese is oxidized, it is uncertain whether manganese will become MnO, Mn₃O₄, Mn₂O₃, MnO₂ or a plurality of mixtures thereof, or whether manganese oxide differs from one another depending on the positions of patterns within a semiconductor device.

### SUMMARY

Some embodiments of the present disclosure provide a manganese silicate film forming method, a processing system for carrying out the manganese silicate film forming method, a semiconductor device manufacturing method using the manganese silicate film forming method and a semiconductor device manufactured by the semiconductor device manufacturing method, which are capable of satisfactorily turning manganese to silicate regardless of the state (valence) of deposited manganese.

The present inventors have thermodynamically studied the reactions of manganese and manganese oxide with a base silicon-containing oxide film. As a result, the present inventors found that the reactions can be classified as follows. (1) When annealed in an oxidizing atmosphere, Mn metal (zero-valent) is oxidized or turned to silicate (Mn of manganese silicate is bivalent). (2) When annealed regardless of an atmosphere (even in an inert atmosphere), MnO (bivalent) among manganese oxides (MnOx) is turned to silicate. (3) When annealed in a reducing atmosphere, Mn₃O₄, Mn₂O₃, and MnO₂ (trivalent and tetravalent) among manganese oxides (MnOx) are turned to silicate. In other words, the atmosphere for forming silicate varies depending on the state (valence) of manganese. As a result of additional studies on the basis of the above result, the present inventors have found that the formation of the silicate can be further enhanced by annealing the manganese film in an oxidizing atmosphere and annealing the manganese film in a reducing atmosphere, after a manganese film is formed. The present disclosure has been completed on the basis of such knowledge.

According to a first aspect of the present disclosure, provided is a manganese silicate film forming method for forming a manganese silicate film by transforming metal manganese to silicate. The manganese silicate film forming method includes forming a metal manganese film on a silicon-containing base by using a manganese compound gas, and annealing the metal manganese film in an oxidizing atmosphere after the formation of the metal manganese film. The manganese silicate film forming method further includes forming a manganese silicate film by annealing the metal manganese film in a reducing atmosphere after the annealing of the metal manganese film in the oxidizing atmosphere.

According to a second aspect of the present disclosure, provided is a processing system for forming a manganese silicate film by transforming metal manganese to silicate. The processing system according to the second aspect includes a degassing unit configured to perform degassing with respect to a target substrate having a silicon-containing base, and a metal manganese film forming unit configured to form a metal manganese film on the degassed target substrate. The processing system according to the second aspect further includes an oxidizing-atmosphere annealing unit configured to anneal, in an oxidizing atmosphere, the target substrate on which the metal manganese film is formed, and a reducing-atmosphere annealing unit configured to anneal, in a reducing atmosphere, the target substrate annealed in the oxidizing atmosphere.

According to a third aspect of the present disclosure, provided is another processing system for forming a manganese silicate film by transforming metal manganese to silicate. The processing system according to the third aspect includes a degassing unit configured to perform degassing with respect to a target substrate having a silicon-containing base, and a metal manganese film forming unit configured to form a metal manganese film on the degassed target substrate. The processing system according to the third aspect further includes an unloading unit configured to unload the target substrate having the metal manganese film formed thereon into a moisture-containing atmosphere, and a reducing-atmosphere annealing unit configured to anneal, in a reducing atmosphere, the target substrate unloaded into the moisture-containing atmosphere.

According to a fourth aspect of the present disclosure, provided is a semiconductor device manufacturing method for manufacturing a semiconductor device including a structure composed of a manganese silicate film. The structure composed of the manganese silicate film is formed by the aforementioned manganese silicate film forming method.

According to a fifth aspect of the present disclosure, provided is a semiconductor device including a structure composed of a manganese silicate film. The structure composed of a manganese silicate film is formed by the aforementioned semiconductor device manufacturing method.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a flowchart illustrating an example of a manganese silicate film forming method according to one embodiment of the present disclosure.

FIGS. 2A through 2F are sectional views showing an instance in which the manganese silicate film forming method according to one embodiment is applied to a semiconductor device manufacturing.

FIG. 3 is a view in which the XPS waveforms of Si 2p are illustrated in a corresponding relationship with the annealing temperatures of the reducing-atmosphere.

FIG. 4 is a view illustrating the temperature dependency of the silicate formation.

FIG. 5 is a view showing a first system configuration example of a processing system carrying out the manganese silicate film forming method according to one embodiment.

FIG. 6 is a view showing a second system configuration example of a processing system carrying out the manganese silicate film forming method according to one embodiment.

### DETAILED DESCRIPTION

Embodiments of the present disclosure will now be described in detail with reference to the accompanying drawings. In the following description and through the drawings, identical parts will be designated by like reference symbols.

### <One Embodiment of Manganese Silicate Film Forming Method>

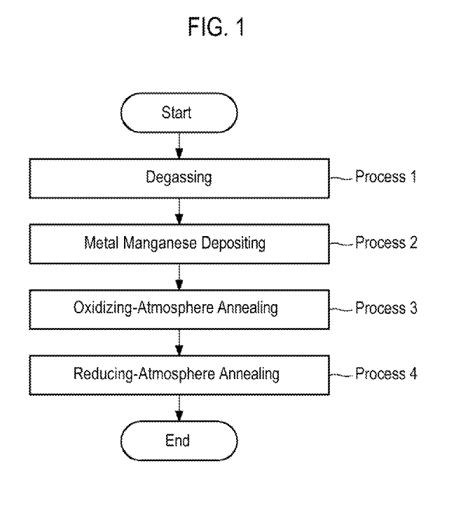

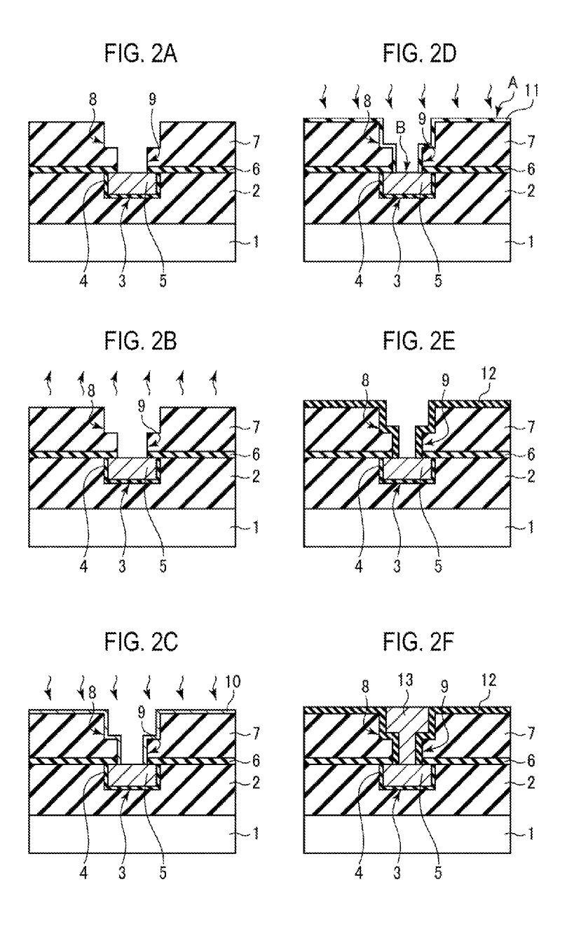

FIG. 1 is a flowchart illustrating an example of a manganese silicate film forming method according to one embodiment of the present disclosure. FIGS. 2A to 2F are sectional views showing an instance in which the manganese silicate film forming method according to one embodiment is applied when manufacturing a semiconductor device. Specifically, in FIGS. 2A to 2F, there is shown an instance in which the manganese silicate film forming method according to one embodiment is applied to the formation of a barrier film. The barrier film as a metal diffusion barrier film is configured to prevent the diffusion of copper existing between a copper wiring line and an interlayer insulating film of a semiconductor device.

In one embodiment, a manganese silicate film is formed on a structure available in manufacturing a semiconductor device as shown in FIG. 2A. In the description of the embodiment, the vicinity of a transistor, namely the process of FEOL (Front End of Line), will be omitted.

### <Structure>

A structure shown in FIG. 2A will be described. A silicon-containing oxide film 2 as a first-layer interlayer insulating film is formed on a semiconductor substrate, e.g., a silicon substrate 1. A groove 3 is formed on the surface of the silicon-containing oxide film 2. A first-layer copper wiring line 5 is formed on a barrier film 4 for preventing the diffusion of copper within the groove 3. A cap barrier film 6 for preventing the diffusion of copper is formed on the silicon-containing oxide film 2 and the first-layer copper wiring line 5. A silicon-containing oxide film 7 as a second-layer interlayer insulating film is formed on the cap barrier film 6. A groove 8 and a via-hole 9 extending from the groove 8 to the first-layer copper wiring line 5 are formed on the surface of the silicon-containing oxide film 7. In the present example, the silicon-containing oxide film 7 becomes a base film on which a metal manganese film is to be formed.

In the structure described above, the silicon-containing oxide film 2 or 7 is, e.g., a silicon oxide film (SiO₂). The SiO₂ is formed by, e.g., a CVD (Chemical Vaporization Deposit) method in which a TEOS (Tetraethoxy Silane) is used as a source gas. However, the source gas is not limited to the TEOS. The SiO₂ may also be obtained by thermally oxidizing silicon.

The silicon-containing oxide film 2 or 7 is not limited to the SiO₂ but may be a silicon-containing oxide film (low-k film) lower in dielectric constant than to the SiO₂, such as SiOC, SiOCH or the like, insofar as the silicon-containing oxide film contains silicon and oxygen. The low-k film containing silicon and oxygen may be a porous low-k film having ‘pores’.

### <Process 1: Degassing Step>

Next, a degassing process, i.e., process 1 shown in FIG. 1, is performed. In this process, as shown in FIG. 2B, the silicon substrate 1 having the structure shown in FIG. 2A is thermally treated to degas surplus moisture and the like adsorbed to the surface of the silicon-containing oxide film 7.

Process 1 is optionally performed, if necessary. The heating temperature and the heating time may be appropriately changed. However, it is preferred that, as in the present embodiment, the surplus moisture and the like adsorbed to the surface of the silicon-containing oxide film 7 as a base film is degassed prior to depositing metal manganese. This is because, if the degassing is insufficient, the manganese oxide film is formed unnecessarily thick or the thickness and composition of the deposited film varies depending on the kind of a wafer. As a result, the reproducibility may be reduced.

### <Process 2: Metal Manganese Depositing Step>

Next, a metal manganese depositing process, i.e., process 2 shown in FIG. 1, is performed. In this process, as shown in FIG. 2C, a metal manganese film 10 is formed on the silicon-containing oxide film 7. At this time, the metal manganese film 10 is also formed on the surface of the silicon-containing oxide film 7 exposed at the lateral sides of the groove 8 and the via-hole 9. However, the metal manganese film 10 is not formed on the surface of the first-layer copper wiring line 5, because the manganese is diffused into the inside of the first-layer copper wiring line 5.

The metal manganese film 10 can be formed by a CVD method using a pyrolysis reaction of a manganese compound gas, a CVD method using a manganese compound gas and a reducing reaction gas, or an ALD (Atomic Layer Deposition) method. Examples of the manganese compound include a cyclopentadienyl-based manganese compound, a carbonyl-based manganese compound, a betadiketone-based manganese compound, an amidinate-based manganese compound, and an amideaminoalkane-based manganese compound. The metal manganese film 10 can be formed by selecting gas of one or more of the manganese compounds.

Examples of the cyclopentadienyl-based manganese compound include bis(alkylcyclopentadienyl) manganese represented by a chemical formula Mn(RC₅H₄)₂.

Examples of the carbonyl-based manganese compound include decacarbonyl 2 manganese (Mn₂(CO)₁₀), methyl cyclopentadienyl tricarbonyl manganese ((CH₃C₅H₄)Mn(CO)₃), cyclopentadienyl tricarbonyl manganese ((C₅H₅)Mn(CO)₃), methyl pentacarbonyl manganese ((CH₃)Mn(CO)₅), and 3-(t-BuAllyl)Mn(CO)₄.

Examples of the betadiketone-based manganese compound include bis(dipivaloylmethanato) manganese (Mn(C₁₁H₁₉O₂)₂), tris(dipivaloylmethanato) manganese (Mn(C₁₁H₁₉O₂)₃), bis(pentanedione) manganese (Mn(C₅H₇O₂)₂), tris(pentanedione) manganese (Mn(C₅H₇O₂)₃), and tris(hexafluoroacetyl) manganese (Mn(C₅HF₆O₂)₃).

Examples of the amidinate-based manganese compound include bis(N,N′-dialkylacetamininate) manganese expressed by a chemical formula Mn(R¹N—CR³—NR²)₂.

Examples of the amideaminoalkane-based manganese compound include bis(N,N′-1-alkylamide-2-dialkylaminoalkane) manganese represented by a chemical formula Mn(R¹N—Z—NR²₂)₂. In the chemical formulae noted above, “R”, “R¹”, “R²” and “R³” are alkyl groups described by —CₙH₂₊₁ (where n is an integer of 1 or greater) and “Z” is an alkylene group described by —CₙH₂ₙ— (where n is an integer of 1 or greater).

Examples of the temperature for forming the metal manganese film in case of using these manganese compounds include: 250 to 300 degrees C. in case of using the amideaminoalkane-based manganese compound; 350 to 400 degrees C. in case of using the amidinate-based manganese compound; 400 to 450 degrees C. in case of using (EtCp)₂Mn; and 450 to 500 degrees C. in case of using MeCpMn(CO)₃. In short, the metal manganese film can be formed at a temperature equal to or higher than the pyrolysis temperature of a precursor. However, if a plasma CVD method is used, it is possible to form the metal manganese film at a lower temperature or a temperature lower than the pyrolysis temperature. Among the manganese compounds stated above, the amideaminoalkane-based manganese compound allows the metal manganese film to be formed at a relatively low temperature, thus it is preferred.

As the reducing reaction gas used in reducing the manganese compounds, it is possible to appropriately use a hydrogen (H₂) gas, a carbon monoxide (CO) gas, an aldehyde (R—CHO) gas such as formaldehyde (HCHO), and a carboxylic acid (R—COOH) gas such as a formic acid (HCOOH). In this regard, “R” is an alkyl group described by —CₙH₂₊₁ (where n is an integer of 0 or greater).

As the method of forming the metal manganese film, it is possible to use a PVD (Physical Vaporization Deposition) method, a PECVD (Plasma Enhanced CVD) method and a PEALD (Plasma Enhanced ALD) method, in addition to the CVD method and the ALD method stated above.

### <Process 3: Oxidizing Atmosphere Annealing Step>

Next, an oxidizing atmosphere annealing process, i.e., process 3 shown in FIG. 1, is performed. In this process, as shown in FIG. 2D, the metal manganese film 10 is first transformed into a manganese oxide (MnOx) film 11 by annealing the metal manganese film 10 in an oxidizing atmosphere. One of MnO, Mn₃O₄, Mn₂O₃ and MnO₂ may be included in the manganese oxide formed in process 3. On the other hand, it may be possible to use a simplex or a mixture of MnO, Mn₃O₄, Mn₂O₃ and MnO₂. In process 3, the metal manganese film 10 may react with the silicon and the oxygen contained in the silicon-containing oxide film 7 and may be partially turned to silicate.

As shown in FIG. 2D, in case of a structure in which a region A of the exposed metal manganese film 10 and a region B of the exposed first-layer copper wiring line 5 are formed together, it is preferable to selectively oxidize the metal manganese film 10 without oxidizing the first-layer copper wiring line 5. This process is performed to suppress the resistance value of a structure made of copper to be increased, as copper is transformed into, e.g., copper oxide. Copper is weaker in oxidizing tendency than manganese and is a hardly-oxidized material. However, if an oxygen partial pressure is high, copper begins to be oxidized. Therefore, in order to selectively oxidize only the manganese, it is preferred that, in process 3, the oxygen partial pressure is maintained at an extremely low oxygen partial pressure of about 10 ppb to about 1 vol %.

As the oxygen for creating the oxidizing atmosphere, it is possible to use the oxygen contained in the silicon-containing oxide film 7 as a base film of the metal manganese film 10 or to use the oxygen adsorbed to the surface of the silicon-containing oxide film 7. It may also be possible to use the oxygen in the moisture or the silanol groups which are contained in or adsorbed to the silicon-containing oxide film 7.

The oxidizing atmosphere can be created by supplying an oxygen-containing gas, e.g., O₂ gas, H₂O gas, CO₂ gas, NO₂ gas or dry air (20% O₂+80% N₂) from the outside into a processing chamber while controlling the flow rate of the oxygen-containing gas.

The annealing temperature in process 3 is in a range of, e.g., from the room temperature (e.g., 25 degrees C.) to 500 degrees C.

### <Process 4: Reducing Atmosphere Annealing Step>

Next, a reducing atmosphere annealing process, i.e., process 4 shown in FIG. 1, is performed. In this process, as shown in FIG. 2E, the manganese oxide film 11 is transformed into a manganese silicate film 12 by annealing the manganese oxide film 11 in a reducing atmosphere. As described above in respect of process 3 before the reducing atmosphere annealing process, the manganese oxide film 11 may include one of MnO, Mn₃O₄, Mn₂O₃ and MnO₂. Further, it may be possible to use a simplex or a mixture of MnO, Mn₃O₄, Mn₂O₃ and MnO₂. Moreover, the manganese oxide film 11 may include manganese silicate.

Examples of the reducing atmosphere include a reducing gas containing hydrogen. Examples of the reducing gas containing hydrogen include foaming gas (3% H₂+97% N₂), aldehyde (R—CHO) gas such as formaldehyde (HCHO) or the like, and carboxylic acid (R—COOH) gas such as formic acid (HCOOH) or the like. In this regard, “R” is an alkyl group described by —CₙH₂₊₁ (where n is an integer of 0 or greater).

In some embodiments, the reducing gas may not contain hydrogen. Examples of the reducing gas not containing hydrogen include carbon monoxide (CO) and so forth.

The annealing temperature in process 4 is in a range of, e.g., 100 to 600 degrees C., and preferably 300 degrees C. or higher.

In process 4, the manganese oxide reacts with the silicon oxide component contained in the silicon-containing oxide film 7 as a base film and becomes silicate, whereby a manganese silicate film 12 is formed on the silicon-containing oxide film 7.

Thereafter, as shown in FIG. 2F, the groove 8 and the via-hole 9 are filled with an electrically conductive metal film, e.g., a copper film. Thus, a second-layer copper wiring line 13 is formed. That is, a barrier film composed of the manganese silicate film 12 is formed between the second-layer copper wiring line 13 and the silicon-containing oxide film 7. In this regard, a metal film made of ruthenium or cobalt may be interposed as an adhesion layer between the second-layer copper wiring line 13 and the manganese silicate film 12. Instead of copper, ruthenium or cobalt may be used as a wiring material. Similarly, the same process for forming the second-layer copper wiring line 13 may be performed to form the first-layer copper wiring line 5.

### <Evaluation Results and Effects of One Embodiment>

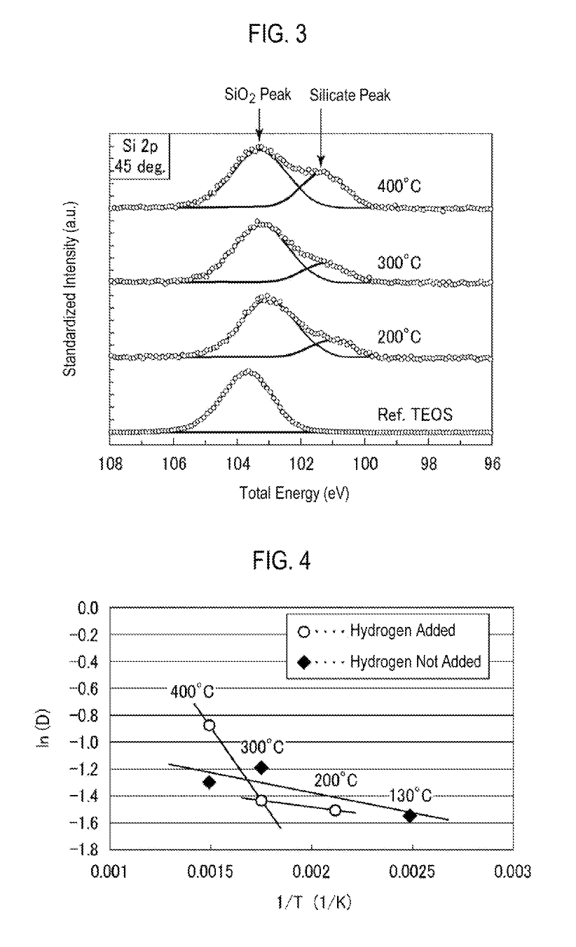

FIG. 3 is a view of the X-ray photoelectron spectroscopy (XPS) waveforms in a binding energy region corresponding to Si 2p. The XPS waveforms are illustrated in a corresponding relationship with the annealing temperatures of the reducing-atmosphere through the use of an X-ray photoelectron spectroscopy (XPS). As shown in FIG. 3, if the annealing is performed, a silicate peak appears in the manganese oxide film (Mn₂O₃) formed on the base silicon-containing oxide film (SiO₂). In the present evaluation, SiO₂ is formed using a TEOS and Mn₂O₃ was formed on SiO₂ using an ALD method. In other words, if the annealing is performed, the silicon-containing oxide film and the manganese oxide film formed thereon react with each other. This reaction initiates the formation of the silicate. As the annealing temperature goes up, the formation of the silicate further proceeds.

Then, the temperature dependency for forming the silicate was examined by comparing a case where the reducing gas is added during the annealing and a case where the reducing gas is not added during the annealing. FIG. 4 is a view showing the temperature dependency for forming the silicate. In FIG. 4, the waveforms in the Si 2p region are separated by the XPS. In this examination, the atom percentages are calculated using the peak considered to be the manganese silicate, and then Arrhenius-plots are performed.

As shown in FIG. 4, it was observed that, even when the reducing gas was not added during the annealing, if the annealing temperature is increased to 130 degrees C., 300 degrees C. and 400 degrees C., the silicate started to form in the manganese oxide film (Mn₂O₃) formed on the silicon-containing oxide film (SiO₂ using a TEOS). However, the progress of the formation of the silicate is gentle. In this embodiment, it is presumed that the MnO component mixed with Mn₂O₃ has made a silicate-forming reaction due to the annealing, considering the mechanism for annealing MnO to be described later.

In contrast, when the reducing gas (hydrogen gas) was added during the annealing, if the annealing temperature is increased to 200 degrees C. and 300 degrees C., the silicon-containing oxide film (SiO₂ using a TEOS) and the manganese oxide film (Mn₂O₃) formed thereon react with each other. Just like the case where the reducing gas was not added, the formation of the silicate proceeds gently, as shown in FIG. 4, which illustrates the slopes of graphs being substantially identical with each other. However, the progress of the formation of the silicate is sharply changed between 300 degrees C. and 400 degrees C. More specifically, if the reducing-atmosphere annealing is performed with respect to the manganese oxide film formed on the silicon-containing oxide film using hydrogen as the reducing gas and if the annealing temperature is set between 300 degrees C. and 400 degrees C., e.g., 350 degrees C. or higher, the progress of the formation of the silicate is accelerated as compared with a case where the annealing is performed without adding the reducing gas. As set forth above, if the reducing gas is added during the annealing, the formation of the silicate accelerates abruptly as the annealing temperature is increased. From the viewpoint of practical use, however, it is preferred that the upper limit of the annealing temperature is 600 degrees C. or lower.

With the manganese silicate film forming method according to one embodiment, the metal manganese film 10 is formed on the base silicon-containing oxide film 7. Thereafter, the metal manganese film 10 is transformed into the manganese oxide film 11 by performing the oxidizing-atmosphere annealing. The silicon oxide component contained in the base silicon-containing oxide film 7 is caused to react with the manganese oxide film 11 by performing the reducing-atmosphere annealing. Thus, the formation of the silicate is accelerated to transform the manganese oxide film 11 into the manganese silicate film 12.

Therefore, even if the manganese oxide film 11 contains any of MnO, Mn₃O₄, Mn₂O₃ and MnO₂ as manganese oxide, it is possible to satisfactorily transform the manganese oxide film 11 into silicate, e.g., MnSiO₃ and/or Mn₂SiO₄, by performing the reducing-atmosphere annealing (process 4).

When the oxidizing-atmosphere annealing (process 3) is performed prior to the reducing-atmosphere annealing, the manganese oxide film 11 may at least partially contain MnSiO₃ and/or Mn₂SiO₄. If the reducing-atmosphere annealing according to one embodiment is additionally performed, it is possible to further advance the formation of the silicate and to increase the percentage of MnSiO₃ and/or Mn₂SiO₄.

This mechanism will be described in more detail with reference to Table 1 provided below. If the oxidizing-atmosphere annealing of process 3 is performed with respect to the metal manganese deposited in process 2, one of MnO, Mn₃O₄, Mn₂O₃, MnO₂ and manganese silicate (MnSiO₃ or Mn₂SiO₄) or a mixture thereof is formed as noted in Cases 1 to 5 in Table 1. If the reducing-atmosphere annealing of process 4 is performed with respect to Cases 1 to 5, the bivalent MnO of Case 1 becomes manganese silicate because it can be transformed into the silicate regardless of the atmosphere. Mn₃O₄, Mn₂O₃ and MnO₂ of Cases 2 to 4 become the bivalent manganese silicate by the reducing-atmosphere annealing since the valence thereof is larger than two. As can be seen in Case 5 below, the manganese silicate formed in process 3 remains unchanged even in the reducing-atmosphere annealing of process 4. As such, even if various manganese oxides are formed by the oxidizing-atmosphere annealing of the metal manganese film, it is possible to reliably transform the manganese oxides to silicate through the next reducing-atmosphere annealing.

TABLE 1

| | | | Process 3 | | Process 4 |
|---|---|---|---|---|---|
| | Process 2 | | Oxidizing- | | Reducing- |
| | Mn-CVD | | Atmosphere | | Atmosphere |
| | Step | | Annealing | | Annealing |
| Case 1 | Mn | → | MnO | → | Manganese Silicate |
| | | | | | (MnSiO₃ or |
| | | | | | Mn₂SiO₄) |
| Case 2 | Mn | → | Mn₃O₄ | → | Manganese Silicate |
| | | | | | (MnSiO₃ or |
| | | | | | Mn₂SiO₄) |
| Case 3 | Mn | → | Mn₂O₃ | → | Manganese Silicate |
| | | | | | (MnSiO₃ or |
| | | | | | Mn₂SiO₄) |
| Case 4 | Mn | → | MnO₂ | → | Manganese Silicate |
| | | | | | (MnSiO₃ or |
| | | | | | Mn₂SiO₄) |
| Case 5 | Mn | → | Manganese Silicate | → | Manganese Silicate |
| | | | (MnSiO₃ or | | (MnSiO₃ or |
| | | | Mn₂SiO₄) | | Mn₂SiO₄) |

The silicate formation reaction depends on the thickness of the metal manganese film formed on the silicon-containing oxide film. Theoretically, a metal manganese film having a thickness of 1 nm is transformed into a manganese silicate film having a thickness of 4.6 nm. The thickness of the manganese silicate film formed in the interface between the metal manganese film and the silicon-containing oxide film is usually about 2.5 nm. Even though the manganese silicate film is formed thick under good conditions, the thickness of the manganese silicate film is only 5 nm. Although the thickness of the metal manganese film is about 0.5 nm, it is possible to almost completely transform the metal manganese film into silicate. If affordable conditions are provided, it is possible to almost completely transform the metal manganese film having a thickness of up to about 1 nm into silicate. Also, the manganese silicate film has a diffusion barrier property. That is, if the thickness of the manganese silicate film grows larger, Mn cannot meet with SiO₂. In this case, the silicate formation reaction is stopped (this phenomenon is called self-limit). Accordingly, it is preferred that the thickness of the metal manganese film is 1 to 1.5 nm or smaller in terms of a continuous film conversion.

According to one embodiment, the manganese silicate film forming method can provide the following additional effects.

(1) Manganese silicate is amorphous and has no grain boundary. For that reason, as compared with a barrier film having a grain boundary, it is possible for the manganese silicate film to improve the barrier property restraining the diffusion of a conductive metal of a semiconductor device into an interlayer insulating film, e.g., the diffusion of copper into an interlayer insulating film.

(2) During the process in which a manganese oxide reacts with a silicon-containing oxide to form manganese silicate, the deposition of the manganese oxide is reduced. In other words, as the formation of the silicate proceeds, the manganese oxide acts as if it corrodes the silicon-containing oxide. For that reason, the height of the manganese oxide becomes smaller at the time of forming the silicate than at the time of forming the manganese oxide, thus approaching a “zero-thickness barrier”. Therefore, the cross-sectional area of the groove 8 and the via-hole 9 becomes larger at the time of forming the silicate than at the time of forming the manganese oxide. As a result of the increase of the cross-sectional area of the groove 8 and the via-hole 9, it is possible to reduce the resistance of conductive metal wiring lines embedded in the groove 8 and the via-hole 9.

(3) The manganese oxide may have different states because the manganese oxide can include MnO, Mn₃O₄, Mn₂O₃ and MnO₂. Thus, the manganese oxide may possibly suffer from variation in density and volume. However, once the manganese silicate (MnSiO₃ or Mn₂SiO₄) is formed, the state of the manganese silicate is more stable than the state of the manganese oxide. Accordingly, after a semiconductor device is manufactured, the over-time degradation of the semiconductor device becomes smaller.

### <Processing System for Forming a Manganese Silicate Film>

Next, description will be made on one example of a processing system carrying out the manganese silicate film forming method according to one embodiment of the present disclosure.

### <First System Configuration Example)>

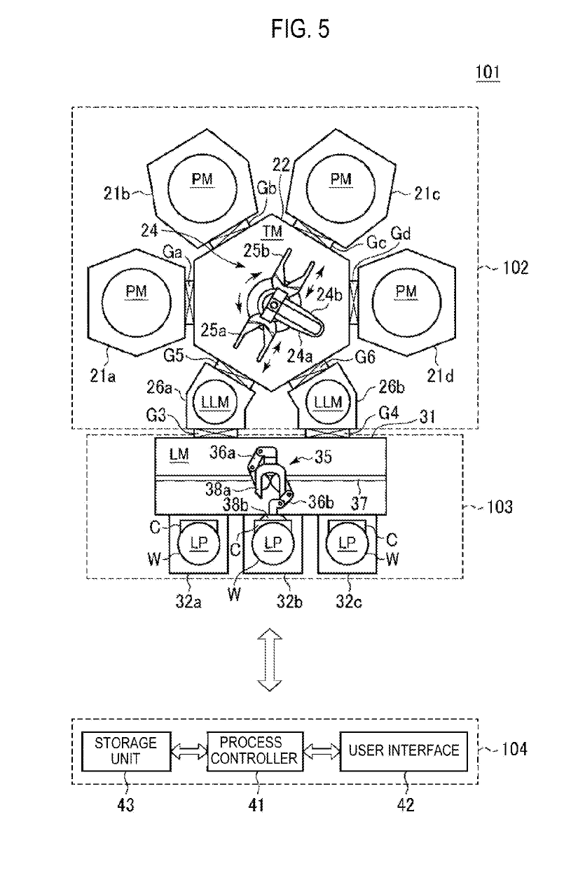

FIG. 5 is a view showing a first system configuration example of a processing system carrying out the manganese silicate film forming method according to one embodiment of the present disclosure.

As shown in FIG. 5, a first processing system 101 includes a processing part 102 for processing a wafer W, a loading/unloading unit 103 for loading and unloading the wafer W into and from the processing part 102 and a control part 104 for controlling the processing system 101. The processing system 101 of the present example is a cluster tool type (multi-chamber type) semiconductor manufacturing apparatus.

The manganese silicate film forming method according to one embodiment of the present disclosure includes four major steps, i.e., steps 1 to 4, as shown in FIG. 1. For that reason, in the first processing system 101, four processing units 21a to 21d for performing the four major steps are arranged around, e.g., a single transfer chamber 22. More specifically, the processing part 102 includes processing units (PM: process modules) 21a to 21d composed of process modules for carrying out different processes. Each of the processing units 21a to 21d is provided with a processing chamber, the inside of which can be depressurized to a specified vacuum degree. Each of steps 1 to 4 is performed in its processing chamber.

The processing unit 21a is a degassing unit for performing process 1. The processing unit 12a performs a degassing process with respect to a base substrate containing silicon, e.g., a target substrate having a silicon-containing oxide. The processing unit 21b is a metal manganese film forming unit for performing process 2. The processing unit 21b forms a metal manganese film on the silicon-containing oxide of the degassed target substrate. The processing unit 21c is an oxidizing-atmosphere annealing unit for performing process 3. In an oxidizing atmosphere, the processing unit 21c anneals the target substrate having the metal manganese film formed thereon. The processing unit 21d is a reducing-atmosphere annealing unit for performing process 4. In a reducing atmosphere, the processing unit 21d anneals the target substrate annealed in the oxidizing atmosphere. The processing units 21a to 21d are connected to a single transfer chamber (TM: transfer module) 22 through gate valves Ga to Gd.

The loading/unloading unit 103 is provided with a loading/unloading chamber (LM: loader module) 31. The loading/unloading chamber 31 is configured so that the internal pressure thereof can be regulated to an atmospheric pressure or a substantially atmospheric pressure, e.g., a pressure a little higher than the ambient atmospheric pressure. In the present example, the loading/unloading chamber 31 has a rectangular shape and includes long sides and short sides orthogonal to the long sides when seen in a plan view. One of the long sides of the loading/unloading chamber 31 is adjacent to the processing part 102. The loading/unloading chamber 31 includes load ports (LP) to which target substrate carriers C for accommodating wafers W are attached. In the present example, three load ports 32a, 32b and 32c are installed along the long side of the loading/unloading chamber 31 opposite from the processing part 102. While the number of the load ports 32a, 32b and 32c is three in the present example, the number of the load ports 32a, 32b and 32c is not limited thereto and may be arbitrary. Shutters not shown are installed in the load ports 32a, 32b and 32c. If the carriers C holding the wafers W or the empty carriers C are attached to the load ports 32a, 32b and 32c, the shutters are removed so that the inside of each of the carriers C can communicate with the inside of the loading/unloading chamber 31 while preventing infiltration of the ambient air.

Load lock chambers (LLM: load lock modules), two load lock chambers 26a and 26b in the present example, are installed between the processing part 102 and the loading/unloading unit 103. Each of the load lock chambers 26a and 26b is configured to switch the internal pressure of the load lock chambers between a negative pressure with a specified vacuum degree and an atmospheric pressure or a substantially atmospheric pressure. The respective load lock chambers 26a and 26b are connected through gate valves G3 and G4 to one side of the loading/unloading chamber 31 opposite from the side along which the load ports 32a, 32b and 32c are installed. The respective load lock chambers 26a and 26b are also connected through gate valves G5 and G6 to two sides of the transfer chamber 22 other than four sides to which the processing units 21a to 21d are connected. Upon opening the gate valve G3 or G4, the load lock chambers 26a and 26b come into communication with the loading/unloading chamber 31. Upon closing the gate valve G3 or G4, the load lock chambers 26a and 26b are disconnected from the loading/unloading chamber 31. Moreover, upon opening the gate valve G5 or G6, the load lock chambers 26a and 26b come into communication with the transfer chamber 22. Upon closing the gate valve G5 or G6, the load lock chambers 26a and 26b are disconnected from the transfer chamber 22.

A loading/unloading mechanism 35 is installed within the loading/unloading chamber 31. The loading/unloading mechanism 35 loads and unloads wafers W into and from the target substrate carriers C. The loading/unloading mechanism 35 is provided with, e.g., two articulated arms 36a and 36b, and is configured to travel along a rail 37 extending in the longitudinal direction of the loading/unloading chamber 31. Hands 38a and 38b are attached to the tip ends of the articulated arms 36a and 36b. The wafer W is placed on the hand 38a or 38b and is loaded and unloaded as stated above.

The transfer chamber 22 is formed of a configuration capable of maintaining a vacuum, e.g., a vacuum vessel. A transfer mechanism 24 for transferring the wafer W between the processing units 21a to 21d and the load lock chambers 26a and 26b is installed within the transfer chamber 22. The wafer W is transferred in a state that the transfer chamber 22 is isolated from the atmosphere. The transfer mechanism 24 is arranged substantially at the center of the transfer chamber 22. The transfer mechanism 24 is provided with, e.g., a plurality of transfer arms capable of making rotational movement and extension and retraction movement. In the present example, the transfer mechanism 24 includes, e.g., two transfer arms 24a and 24b. Holders 25a and 25b are attached to the tip ends of the transfer arms 24a and 24b. The wafer W is held by the holders 25a or 25b. As stated above, the wafer W is transferred between the processing units 21a to 21d and the load lock chambers 26a and 26b.

The control part 104 includes a process controller 41, a user interface 42 and a storage unit 43. The process controller 41 includes a microprocessor (computer). The user interface 42 includes a keyboard by which an operator performs a command input operation to manage the processing system 101 and a display for visually displaying the operation status of the processing system 101. The storage unit 43 stores a control program for realizing, under the control of the process controller 41, the process carried out in the processing system 101, different kinds of data, and recipes for causing the processing system 101 to carry out processes pursuant to process conditions. The recipes are stored in a storage medium of the storage unit 43. The storage medium is computer-readable. The storage medium may be, e.g., a hard disk or a portable storage medium such as a CD-ROM, a DVD or a flash memory. The recipes may be appropriately transmitted from an external device through, e.g., a dedicated line. An arbitrary recipe is called out from the storage unit 43 pursuant to the instruction received from the user interface 42 and is executed in the process controller 41. Accordingly, under the control of the process controller 41, the manganese silicate film forming method according to one embodiment is carried out with respect to a target substrate on which a manganese silicate film is to be formed.

The manganese silicate film forming method according to one embodiment can be carried out by the processing system shown in FIG. 5.

### <Second System Configuration Example>

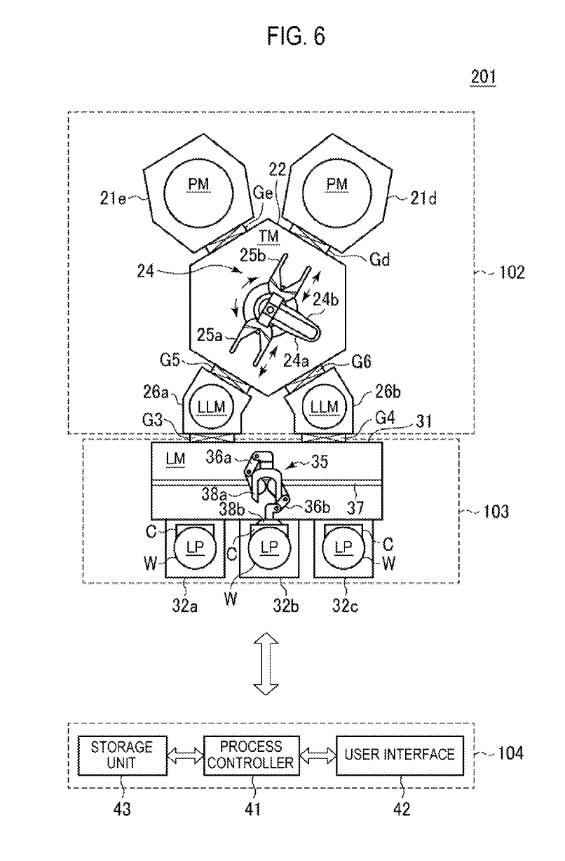

FIG. 6 is a view showing a second system configuration example of a processing system carrying out the manganese silicate film forming method according to one embodiment of the present disclosure.

Referring to FIG. 6, the second processing system 201 differs from the first processing system 101 in that the degassing unit, the metal manganese film forming unit and the oxidizing-atmosphere annealing unit are formed into a single processing module. Therefore, the second processing system 201 includes a processing unit 21e as a processing module for performing a degassing process, a metal manganese film forming process and an oxidizing-atmosphere annealing process, and a processing unit 21d as a processing module for performing a reducing-atmosphere annealing process. In other respects, the second processing system 201 remains substantially the same as the first processing system 101.

In the specific configuration of the processing unit 21e, a gas supply line for supplying an oxidizing atmosphere gas may be added to the processing unit 21b as a metal manganese film forming unit shown in FIG. 5. The degassing process is performed by heating the target substrate through the use of a heating device arranged in the processing unit 21e. After the degassing process, a metal manganese film 10 is formed on the target substrate. If the formation of the metal manganese film 10 is completed, an oxidizing atmosphere gas is supplied into the processing chamber, thereby transforming the metal manganese film 10 to a manganese oxide film 11.

The manganese silicate film forming method according to one embodiment can be carried out by the processing system shown in FIG. 6.

While the present disclosure has been described on the basis of one embodiment, the present disclosure is not limited to one embodiment described above but may be appropriately modified without departing from the spirit and scope of the disclosure. One embodiment described above is not a sole embodiment of the present disclosure.

For example, in one embodiment described above, the oxidizing-atmosphere annealing process as process 3 can be replaced by a process of exposing a previously formed metal manganese film to an atmosphere containing moisture. In this case, the metal manganese film 10 is oxidized by the moisture contained in the atmosphere and is transformed into a manganese oxide film 11. It goes without saying that, at this time, heating may be used in combination. Thereafter, the reducing-atmosphere annealing of process 4 is performed. This makes it possible to obtain the same effects as obtained in one embodiment described above.

In case where the oxidizing-atmosphere annealing process is replaced by the process of exposing the metal manganese film to the atmosphere containing moisture, the oxidizing-atmosphere annealing unit becomes unnecessary in the processing system. For that reason, the target substrate may be taken out from the processing system by an unloading unit after it is processed in the metal manganese film forming unit for performing process 2. Outside the processing system, the target substrate may be exposed to an atmosphere containing moisture, e.g., an atmosphere of specified humidity. Thereafter, the target substrate may be transferred to the reducing-atmosphere annealing unit. In this case, the reducing-atmosphere annealing unit can be installed independently of the processing system. Therefore, the reducing-atmosphere annealing unit can be formed into a batch type using a vertical furnace. Also, in this case, since the oxidizing-atmosphere annealing unit becomes unnecessary, the above second processing system 201 may include a processing unit 21e as a processing module for performing both degassing process and metal manganese film forming process, and a processing unit 21d as a processing module for performing a reducing-atmosphere annealing process.

In one embodiment described above, the formation of a conductive metal film, e.g., the formation of a copper film, is performed after carrying out the reducing-atmosphere annealing of process 4. However, the formation of a conductive metal film, e.g., the formation of a copper film, can be performed after carrying out the metal manganese film deposition of process 2 but before carrying out the oxidizing-atmosphere annealing or the reducing-atmosphere annealing. This is because, just like the annealing in an atmosphere added with, e.g., a small amount of oxygen, the oxidizing-atmosphere annealing and the reducing-atmosphere annealing employed in the aforementioned embodiment are effective even though they are performed after formation of a copper film on the metal manganese film.

The target substrate is not limited to the semiconductor wafer but may be a glass substrate used in the manufacture of a solar cell or an FPD. The present disclosure is not limited to the manganese silicate. Needless to say, the present disclosure may be applied to an element capable of forming silicate (e.g., Mg, Al, Ca, Ti, V, Fe, Co, Ni, Sr, Y, Zr, Ba, Hf or Ta).

According to the present disclosure, it is possible to provide a manganese silicate film forming method, a processing system for carrying out the manganese silicate film forming method, a semiconductor device manufacturing method using the manganese silicate film forming method and a semiconductor device manufactured by the semiconductor device manufacturing method, which are capable of satisfactorily turning manganese to silicate regardless of the state (valence) of deposited manganese.

While certain embodiments have been described, these embodiments have been presented by way of example only, and are not intended to limit the scope of the disclosures. Indeed, the novel methods, systems and semiconductor devices described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A manganese silicate film forming method for forming a manganese silicate film by transforming metal manganese to silicate, comprising:
forming a metal manganese film on a silicon-containing base by using a manganese compound gas;
annealing the metal manganese film in an oxidizing atmosphere after forming the metal manganese film; and
forming a manganese silicate film by annealing the metal manganese film in a reducing atmosphere after annealing the metal manganese film in the oxidizing atmosphere.

2. The method of claim 1, wherein the manganese compound gas is selected from the group consisting of a cyclopentadienyl-based manganese compound gas, a carbonyl-based manganese compound gas, a betadiketone-based manganese compound gas, an amidinate-based manganese compound gas and an amideaminoalkane-based manganese compound gas.

3. The method of claim 2, wherein the cyclopentadienyl-based manganese compound gas is a manganese compound gas represented by a chemical formula Mn(RC₅H₄)₂.

4. The method of claim 2, wherein the carbonyl-based manganese compound gas is selected from the group consisting of Mn₂(CO)₁₀, (CH₃C₅H₄)Mn(CO)₃, (C₅H₅)Mn(CO)₃, (CH₃)Mn(CO)₅ and 3-(t-BuAllyl)Mn(CO)₄.

5. The method of claim 2, wherein the betadiketone-based manganese compound gas is selected from the group consisting of Mn(C₁₁H₁₉O₂)₂, Mn(C₁₁H₁₉O₂)₃, Mn(C₅H₇O₂)₂, Mn(C₅H₇O₂)₃ and Mn(C₅HF₆O₂)₃.

6. The method of claim 2, wherein the amidinate-based manganese compound gas is a manganese compound gas represented by a chemical formula Mn(R¹N—CR³—NR²)₂.

7. The method of claim 2, wherein the amideaminoalkane-based manganese compound gas is a manganese compound gas expressed by a chemical formula Mn(R¹N—Z—NR²₂)₂.

8. The method of claim 1, further comprising degassing by performing heating prior to forming the metal manganese film on the silicon-containing base.

9. The method of claim 1, wherein in case that the surface of the silicon-containing base comprises a first portion from which a structure including copper is exposed and a second portion which is other than the first portion, and in case that the metal manganese film is formed on the second portion, an oxygen partial pressure in the oxidizing atmosphere is maintained in a range of 10 ppb to 1 vol %.

10. The method of claim 1, wherein annealing the metal manganese film in the oxidizing atmosphere is replaced by exposing the metal manganese film to a moisture-containing atmosphere after forming the metal manganese film.

11. The method of claim 1, wherein annealing the metal manganese film in the reducing atmosphere is performed at annealing temperature of 100 degrees C. to 600 degrees C.

12. The method of claim 1, wherein the reducing atmosphere contains hydrogen or carbon monoxide.

13. The method of claim 12, wherein annealing the metal manganese film in the reducing atmosphere is performed at annealing temperature of 300 degrees C. to 600 degrees C.

14. The method of claim 1, further comprising forming a conductive metal film after forming the manganese silicate film by annealing the metal manganese film in the reducing atmosphere or after forming the metal manganese film but before annealing the metal manganese film in the oxidizing atmosphere.

15. A processing system for forming a manganese silicate film by transforming metal manganese to silicate, comprising:
a degassing unit configured to perform degassing with respect to a target substrate having a silicon-containing base;
a metal manganese film forming unit configured to form a metal manganese film on the degassed target substrate;
an oxidizing-atmosphere annealing unit configured to anneal, in an oxidizing atmosphere, the target substrate on which the metal manganese film is formed; and
a reducing-atmosphere annealing unit configured to anneal, in a reducing atmosphere, the target substrate annealed in the oxidizing atmosphere.

16. The system of claim 15, wherein the degassing unit, the metal manganese film forming unit and the oxidizing-atmosphere annealing unit are formed into a single processing module.

17. A processing system for forming a manganese silicate film by transforming metal manganese to silicate, comprising:
a degassing unit configured to perform degassing with respect to a target substrate having a silicon-containing base;
a metal manganese film forming unit configured to form a metal manganese film on the degassed target substrate;
an unloading unit configured to unload the target substrate having the formed metal manganese film into a moisture-containing atmosphere; and
a reducing-atmosphere annealing unit configured to anneal, in a reducing atmosphere, the target substrate unloaded into the moisture-containing atmosphere.

18. The system of claim 17, wherein the degassing unit and the metal manganese film forming unit are formed into a single processing module.

19. The system of claim 17, wherein the reducing-atmosphere annealing unit is a batch type.

20. A method for manufacturing a semiconductor device, the semiconductor device including a structure composed of a manganese silicate film, wherein the structure composed of the manganese silicate film is formed by the manganese silicate film forming method according to any one of claim 1.

21. The method of claim 20, wherein the structure composed of the manganese silicate film is a metal diffusion barrier film formed between a conductive metal wiring line and an interlayer insulating film.

22. The method of claim 21, wherein a conductive metal of the conductive metal wiring line includes one or more elements selected from the group consisting of copper, ruthenium and cobalt.

23. A semiconductor device comprising a structure composed of a manganese silicate film formed by the semiconductor device manufacturing method of claim 20.

24. The device of claim 23, wherein the structure composed of the manganese silicate film is a metal diffusion barrier film formed between a conductive metal wiring line and an interlayer insulating film.

25. The device of claim 24, wherein a conductive metal of the conductive metal wiring line includes one or more elements selected from the group consisting of copper, ruthenium and cobalt.
